(19) United States
(12) Patent Application Publication
(10) Pub. No.: US 2012/0266034 A1
(43) Pub. Date: Oct. 18, 2012

(54) SEMICONDUCTOR MEMORY DEVICE AND TEST METHOD THEREOF

(76) Inventor: Sang-Hoon SHIN, Gyeonggi-do (KR)

(21) Appl. No.: 13/333,856

(22) Filed: Dec. 21, 2011

(30) Foreign Application Priority Data
Apr. 15, 2011 (KR) 10-2011-0035054

(51) Int. Cl. G11C 29/10; G06F 11/26

(52) U.S. Cl. 714/719; 714/E11.159

(57) ABSTRACT

A semiconductor memory device includes a plurality of memory cells; a data comparison section configured to compare input data to be stored in the memory cells with output data outputted from the memory cells in a test operation, an address storage section configured to store addresses corresponding to defected memory cells of the memory cells in response to a comparison result of the data comparison section, and a comparison period control section configured to generate a period control signal for controlling an activation period of the data comparison section.

### CROSS-REFERENCE TO RELATED APPLICATIONS

The present application claims priority of Korean Patent Application No. 10-2011-0035054, filed on Apr. 15, 2011, which is incorporated herein by reference in its entirety.

### BACKGROUND

1. Field

Exemplary embodiments of the present invention relate to semiconductor design technology, and particularly, to a semiconductor memory device having a test circuit therein.

2. Description of the Related Art

In general, a semiconductor memory device such as a double data rate synchronous DRAM (DDR SDRAM) passes through various tests operation, before being a product, and obtains the reliability of a circuit operation through such a test operation. A test circuit for testing the semiconductor memory device is generally provided outside the semiconductor memory device, but may also be provided in the semiconductor memory device.

A test circuit (hereinafter, referred to as an “internal test circuit”) provided in the semiconductor memory device is arranged in a peripheral circuit area with a relatively large area margin, compared to other areas, e.g., a cell area. However, as the peripheral circuit area has less area margin due to the high integration of the semiconductor memory device, there is a burden in designing the internal test circuit even in the peripheral circuit area. In this regard, an internal test circuit with a small area is useful.

### SUMMARY

An embodiment of the present invention is directed to a semiconductor memory device including an internal test circuit with a minimum area.

In accordance with an embodiment of the present invention, a semiconductor memory device includes: a plurality of memory cells; a data comparison section configured to compare input data to be stored in the memory cells with output data outputted from the memory cells in a test operation; an address storage section configured to store addresses corresponding to defective memory cells of the memory cells in response to a comparison result of the data comparison section; and a comparison period control section configured to generate a period control signal for controlling an activation period of the data comparison section.

In accordance with an embodiment of the present invention, a method for testing a semiconductor memory device includes: primarily detecting a first defective address in response to first selected ones of addresses corresponding to a plurality of memory cells in a test operation mode; outputting the detected address; and secondarily detecting a second defective address in response to second selected ones of the addresses, wherein the second selected addresses are different from the first selected addresses.

In accordance with an embodiment of the present invention, a method for testing a semiconductor memory device includes: performing a first test operation in response to first selected ones of addresses corresponding to a plurality of memory cells; outputting a test result of the first test operation; and performing a second test operation in response to second selected ones of the addresses, wherein the second selected addresses are different from the first selected addresses.

The semiconductor memory device in accordance with the embodiment of the present invention may control an address period for comparing test data, thereby minimizing the area of an address storage circuit.

### BRIEF DESCRIPTION OF THE DRAWINGS

FIG. 1 is a block diagram illustrating a semiconductor memory device in accordance with an embodiment of the present invention.

FIG. 2 is a block diagram illustrating a comparison period control section 153 of FIG. 1 in accordance with a first embodiment.

FIG. 3 is a flowchart illustrating a test method of a semiconductor memory device in accordance with an embodiment of the present invention.

FIG. 4 is a block diagram illustrating a comparison period control section 153 of FIG. 1 in accordance with a second embodiment.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

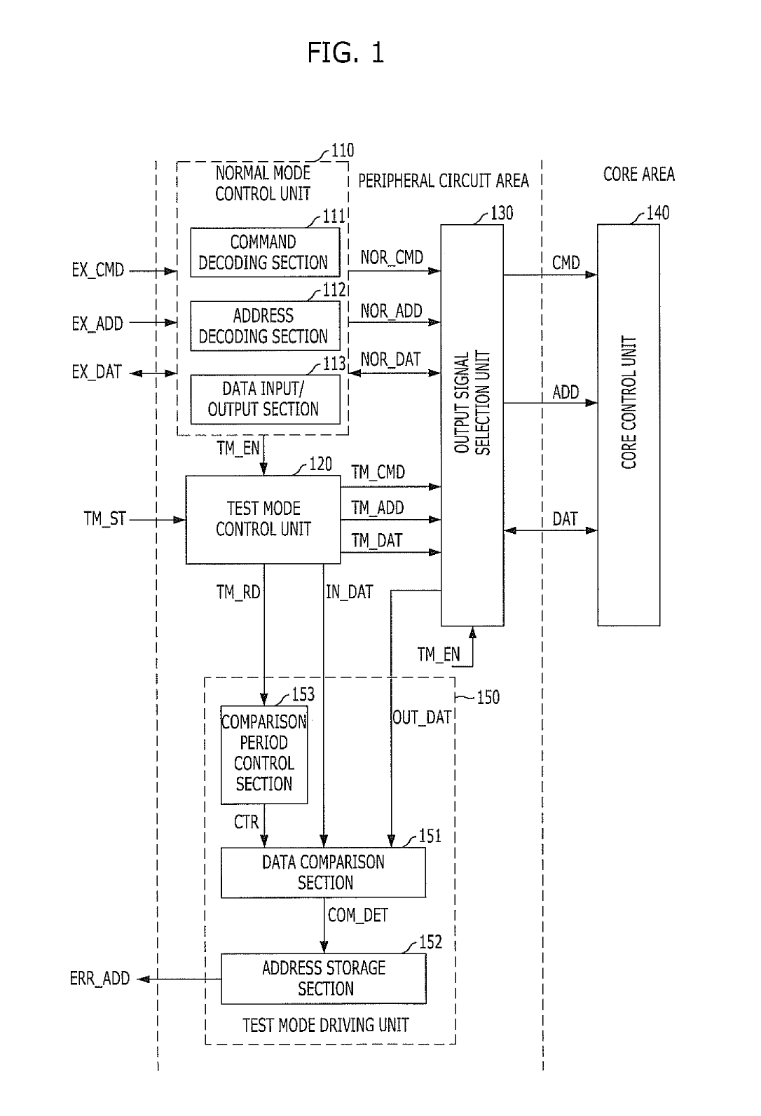

FIG. 1 is a block diagram illustrating a semiconductor memory device in accordance with an embodiment of the present invention.

Referring to FIG. 1, the semiconductor memory device includes a normal mode control unit 110, a test mode control unit 120, an output signal selection unit 130, a core control unit 140, and a test mode driving unit 150.

The normal mode control unit 110 is configured to receive and process an external command signal EX_CMD, an external address signal EX_ADD, and an external data signal EX_DAT, which are output from an external circuit such as a chipset, and generate a normal command signal NOR_CMD, a normal address signal NOR_ADD, and a normal data signal NOR_DAT. To this end, the normal mode control unit 110 includes a command decoding section 111, an address decoding section 112, and a data input/output section 113.

The command decoding section 111 is configured to decode the external command signal EX_CMD, such as a row address strobe signal RAS, a column address strobe signal CAS, a chip select signal CS, and a write enable signal WE, and output the normal command signal NOR_CMD. The generated normal command signal NOR_CMD is used to control a read operation, a write operation, a precharge operation and the like in a normal operation mode. The address decoding section 112 is configured to decode the external address signal EX_ADD and output the normal address signal NOR_ADD, and the data input/output section 113 is configured to receive the external data signal EX_DAT and output the normal data signal NOR_DAT.

The test mode control unit 120 is configured to generate a test command signal TM_CMD, a test address signal TM_ADD, and a test data signal TM_DAT in a test operation mode. The test mode control unit 120 enters the test operation mode in response to a test enable signal TM_EN and performs a test operation in response to a test start signal TM_ST. The test enable signal TM_EN and the test start signal TM_ST may be directly received from an exterior or may be generated in the test mode control unit 120. In the embodiment, the test enable signal TM_EN is generated by decoding the external command signal EX_CMD, and the test start signal TM_ST is received from an exterior. The test command signal TM_CMD, the test address signal TM_ADD, and the test data signal TM_DAT are generated by the test mode control unit 120 in response to the test operation mode.

The output signal selection unit 130 is configured to output the normal command signal NOR_CMD, the normal address signal NOR_ADD, and the normal data signal NOR_DAT, which are the output signals of the normal mode control unit 110, in response to the normal operation mode and output the test command signal TM_CMD, the test address signal TM_ADD, and the test data signal TM_DAT, which are the output signals of the test mode control unit 120, in response to the test operation mode. The output signal selection unit 130 outputs the output signals NOR_CMD, NOR_ADD, and NOR_DAT of the normal mode control unit 110 or the output signals TM_CMD, TM_ADD, and TM_DAT of the test mode control unit 120 in response to the test enable signal TM_EN. The test enable signal TM_EN corresponds to the normal operation mode and the test operation mode.

The core control unit 140 is configured to receive a command signal CMD, an address signal ADD, and a data signal DAT, which are selected by the output signal selection unit 130, and perform an operation corresponding to the command signal CMD. In further detail, the core control unit 140 performs a read operation, a write operation, a precharge operation and the like in the normal operation mode and the test operation mode. In the write operation, data is stored in memory cells (not illustrated) provided in the core control unit 140. In the read operation, the data stored in the memory cells is output.

Last, the test mode driving unit 150 is configured to analyze the data signal DAT output from the core control unit 140 and generate an address corresponding to a defective memory cell in the read operation of the test operation mode, and it includes a data comparison section 151, an address storage section 152, and a comparison period control section 153.

The data comparison section 151 is configured to compare data (that is, input data IN_DAT), which is to be stored in the memory cells of the core control unit 140 in response to the write operation in the test operation mode, with data (that is, output data OUT_DAT), which is output from the memory cells of the core control unit 140 in response to the read operation. If the memory cell of the core control unit 140 is a defective cell, the input data IN_DAT is different from the output data OUT_DAT, and the data comparison section 151 outputs a comparison detection signal COM_DET as a comparison result.

The address storage section 152 is configured to store an address corresponding to the defective cell in response to the comparison detection signal COM_DET. In other words, when the data comparison section 151 compares the input data IN_DAT with the output data OUT_DAT, if the memory cell is defective, the output data OUT_DAT become defective data and has a data value different from that of the input data IN_DAT input in the read operation. At this time, the address storage section 152 stores the address corresponding to the defective data, i.e. the defective cell. The address storage section 152 in accordance with the embodiment of the present invention may be designed to have an optimized area, which will be described later.

The comparison period control section 153 is configured to control an activation period of the data comparison section 151. That is, the comparison period control section 153 is activated in response to a test read command signal TM_RD which is output from the test mode control unit 120 and generates a period control signal CTR for controlling a period in which the data comparison section 151 performs the comparison operation. The test read command signal TM_RD is activated when the read operation of the test operation mode is performed.

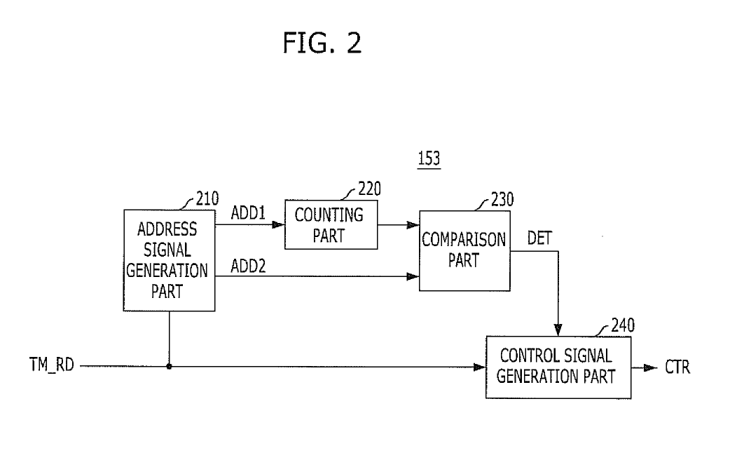

Hereinafter, the period control signal CTR will be described with reference to FIGS. 2 to 4.

FIG. 2 is a block diagram illustrating the comparison period control section 153 of FIG. 1 in accordance with a first embodiment.

Referring to FIG. 2, the comparison period control section 153 includes an address signal generation part 210, a counting part 220, a comparison part 230, and a control signal generation part 240.

The address signal generation part 210 is configured to generate first and second address signals ADD1 and ADD2 in response to the test read command signal TM_RD. The number of addresses defined by the first and second address signals ADD1 and ADD2 is smaller than the number of all addresses corresponding to all memory cells, which may be defined by the external address signal EX_ADD. For example, if the number of addresses corresponding to all memory cells is 2^{B}, the number of addresses defined by the first and second address signals ADD1 and ADD2 may be 2⁶.

The counting part 220 is configured to receive and count the first address signal ADD1, and the comparison part 230 is configured to compare a counting address signal output from the counting part 220 with the second address signal ADD2, detect address values of the two address signals, and activate a detection signal DET when they are substantially equal to each other. The control signal generation part 240 is configured to generate the period control signal CTR having an activation period which is defined in response to the test read command signal TM_RD and the detection signal DET. Accordingly, the period control signal CTR may be a pulse signal which is activated in response to the test read command signal TM_RD and is deactivated in response to the detection signal DET.

With reference to Table 1 below, the operation of the circuit of FIG. 2 will be briefly described.

TABLE 1

| | ADD1 | ADD2 |
|---|---|---|
| First | 00000000 | 00011111 |
| Second | 00100000 | 00111111 |
| Third | 01000000 | 01011111 |
| Fourth | 01100000 | 01111111 |
| Fifth | 10000000 | 10011111 |
| Sixth | 10100000 | 10111111 |
| Seventh | 11000000 | 11011111 |
| Eighth | 11100000 | 11111111 |

For the purpose of description, it is described as an example that the number of addresses defined by the first and second address signals ADD1 and ADD2 is 2⁶. That is, the period control signal CTR is activated in response to the test read command signal TM_RD and is deactivated in response to the detection signal DET which is activated after the first address signal ADD1 is counted by 2⁵.

Hereinafter, the test operation mode will be described with reference to FIG. 1 and FIG. 2.

In the write operation of the test operation mode, the test mode control unit 120 generates the test command signal TM_CMD, the test address signal TM_ADD, and the test data signal TM_DAT corresponding to the write operation, and the test command signal TM_CMD, the test address signal TM_ADD, and the test data signal TM_DAT are input to the core control unit 140 through the output signal selection unit 130. Through such a write operation, data values corresponding to the test data signal TM_DAT are stored in the memory cells provided in the core control unit 140.

In the read operation of the test operation mode, the test mode driving unit 150 is activated in response to the test read command signal TM_RD generated by the test mode control unit 120. The period control signal CTR is activated in response to the test read command signal TM_RD, the data comparison section 151 compares the input data IN_DAT with the output data OUT_DAT, and the address storage section 152 stores an address (hereinafter, referred to as a “defective address”) corresponding to defective data in response to the comparison detection signal COM_DET which is output from the data comparison section 151. Such an operation is performed during the activation period of the period control signal CTR. That is, until the addresses are counted from ‘00000000’ corresponding to the first address ADD1 (a first address) to ‘00011111’ corresponding to the second address ADD1 (a last address), a first read operation of the test operation mode is performed. When the period control signal CTR is deactivated, the data comparison section 151 stops the comparison operation, and the address storage section 152 outputs a defective address ERR_ADD which is an address corresponding to the defective data. A test operator analyzes the semiconductor memory device based on the defective address ERR_ADD obtained through the first read operation.

After the first read operation of the test operation mode is performed, the address signal generation part 210 sets the first and second address signals ADD1 and ADD2 as shown in Table 1 above in response to a second read operation and performs an operation substantially equal to the first read operation. Through such a series of test operations, the test operator may detect whether or not a defect has been caused in all the memory cells.

As described above, the address storage section 152 stores the defective address ERR_ADD generated in the address period defined by the first and second address signals ADD1 and ADD2. With the development of process technology, a defect may be caused in a small number of memory cells. In this regard, the address storage section 152 may be designed to have a small number of address storage circuits.

As set in Table 1 above, the same test operation may be performed with respect to the periods by the number of times desired by the test operator. The reason for performing such an operation is because a memory cell of a specific defect may not be detected through a one-time test operation. Thus, a test operation may be repeatedly performed for the same period of addresses to detect such a defective memory cell.

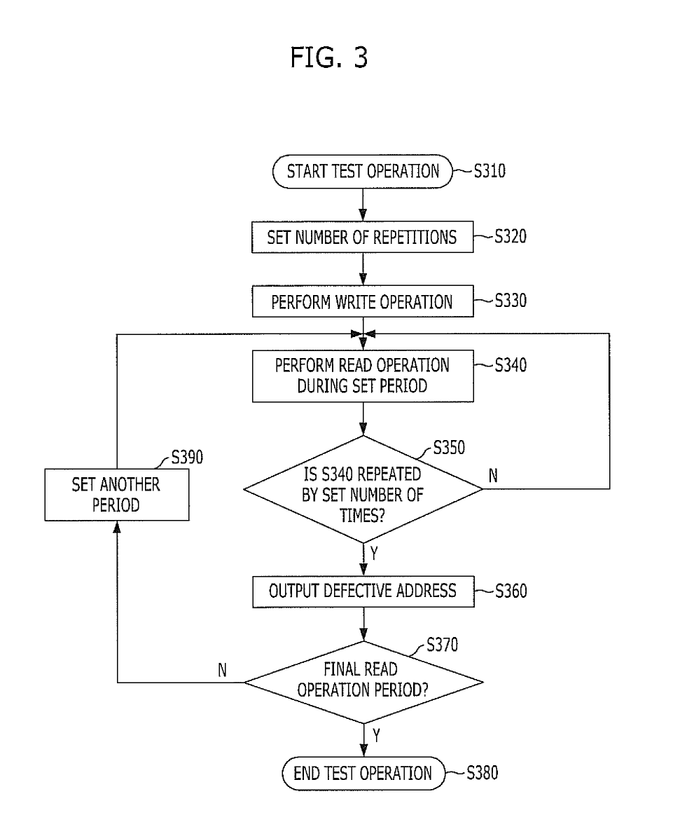

FIG. 3 is a flowchart illustrating a test method of the semiconductor memory device in accordance with the embodiment of the present invention.

Referring to FIG. 3, the test method of the semiconductor memory device includes step S310 in which a test operation starts, step S320 in which the number of repetitions is set, step S330 in which a write operation is performed, step S340 in which a read operation is performed during a set period, step S350 in which it is determined whether the read operation has been performed by the set number of repetition times, step S360 in which a defective address is output, step S370 in which it is determined whether a current period is a last read operation period, step S380 in which the test operation is ended, and step S390 in which another period is set.

Hereinafter, the test method of the semiconductor memory device in accordance with the embodiment of the present invention will be described.

In step S320 after step S310, how many numbers of times the set period is to be tested is set. In step S330, the write operation is performed and certain test data is stored in memory cells. In step S340, the above-mentioned read operation of the test operation mode is performed. As described above, the read operation of the test operation mode is performed on variously divided periods, and step S340, for example, may correspond to one of the read operation periods of Table 1 above. After all read operations have been performed for the set period in step S340, it is determined whether step S340 has been repeated by the set number of times in step S350. As a determination result of step S350, when step S340 has been repeated by the set number of times (Y), step S360 is performed. However, when step S340 has not been repeated by the set number of times (N), step S340 is performed again.

In step S360, a defective address is output and provided to a test operator. In step S370, it is determined whether step S340 is performed for a period corresponding to the last read operation period. That is, in step S370, it is determined whether the read operation has been performed for all memory cells. If the read operation has been performed for all memory cells (Y), the test operation is ended in step S380. When read operation has not been performed for all memory cells (N), another period is set in step S390, and step S340 is performed again.

In the semiconductor memory device in accordance with the embodiment of the present invention, a test operation may be repeatedly performed by the set number of times for a subset (e.g., selected addresses) of all the addresses through the test operation mode, thereby obtaining a more accurate test result.

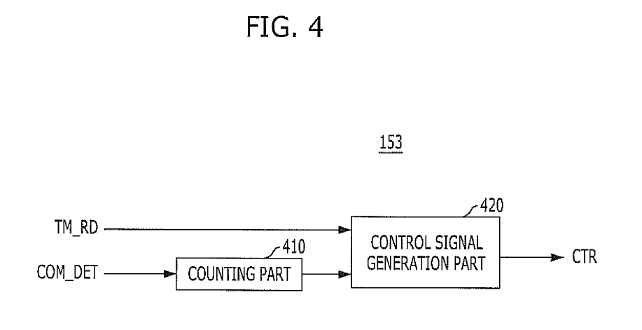

FIG. 4 is a block diagram illustrating the comparison period control section 153 of FIG. 1 in accordance with a second embodiment.

Referring to FIG. 1 and FIG. 4, the comparison period control section 153 includes a counting part 410 and a control signal generation part 420.

The counting part 410 is configured to count the comparison detection signal COM_DET generated by the data comparison section 151 up to a limit setting value, and the control signal generation part 420 is configured to generate the period control signal CTR in response to the test read command signal TM_RD and the output signal of the counting part 410. For example, when the limit setting value of the counting part 410 is set to ‘10’, the counting part 410 performs a counting operation on the activation of the comparison detection signal COM_DET by the set number of times ‘10’, that is, the output signal of the counting part 410 is activated when the comparison detection signal COM_DET is activated ten times. The period control signal CTR is activated in response to the test read command signal TM_RD and is deactivated in response to the output signal of the counting part 410. As a consequence, the period control signal CTR is deactivated at the time point when the comparison detection signal COM_DET is activated by the number of times corresponding to the limit setting value.

The comparison detection signal COM_DET generated by the data comparison section 151 is activated in response to defective data. In this regard, the period control signal CTR in accordance with the second embodiment of the present invention is deactivated at the time point when the number of the defective data reaches the limit setting value. In such a case, the address storage section 152 may be provided with storage circuits of a number corresponding to the limit setting value. This represents that the address storage section 152 may be designed to have a minimum area.

The semiconductor memory device in accordance with the embodiment of the present invention may control an address period for comparing test data to minimize the area of an address storage circuit, resulting in a reduction of a chip size of the semiconductor memory device. Furthermore, since the reliability of a test result is high, a test analysis time and a product development term may be shortened.

In the semiconductor memory device in accordance with the embodiment of the present invention, a read operation is preferentially performed in response to a part of all addresses in a test operation mode, a test result value for the read operation is output, and the read operation is performed for remaining addresses. However, the semiconductor memory device in accordance with the embodiment of the present invention may also be applied to other operations other than the read operation of the test operation mode, and different test operations as well as the same test operation may be performed for respective divided address periods.

According to the present invention, the area of an internal test circuit is minimized, so that the chip size of a semiconductor memory device may be reduced.

Furthermore, according to the present invention, a test analysis time is shortened based on an accurate test result, so that a product development term may be shortened.

While the present invention has been described with respect to the specific embodiments, it will be apparent to those skilled in the art that various changes and modifications may be made without departing from the spirit and scope of the invention as defined in the following claims.

In addition, the position and type of the logic gate and transistor described in the above-mentioned embodiment may be changed according to the polarity of an input signal.

What is claimed is:

1. A semiconductor memory device comprising:
a plurality of memory cells;
a data comparison section configured to compare input data to be stored in the memory cells with output data outputted from the memory cells in a test operation;
an address storage section configured to store addresses corresponding to defective memory cells of the memory cells in response to a comparison result of the data comparison section; and
a comparison period control section configured to generate a period control signal for controlling an activation period of the data comparison section.

2. The semiconductor memory device of claim 1, wherein the period control signal is activated to control a test operation period for some of addresses corresponding to the memory cells.

3. The semiconductor memory device of claim 1, wherein the period control signal is activated during a test operation for some of addresses corresponding to the memory cells.

4. The semiconductor memory device of claim 1, wherein the comparison period control section comprises:
an address signal generation part configured to generate a first address and a last address of selected ones of addresses corresponding to the memory cells;
a counting part configured to perform a counting operation in response to the first address;
a comparison part configured to compare an output address of the counting part with the last address; and
a control signal generation part configured to generate the period control signal which is activated in response to the test operation and the selected ones of the addresses.

5. The semiconductor memory device of claim 1, wherein the period control signal is activated in response to the test operation and deactivated at a time point when a number of the defective memory cells reaches a limit setting value.

6. The semiconductor memory device of claim 5, wherein the address storage section including storage units of a number corresponding to the limit setting value.

7. The semiconductor memory device of claim 1, wherein the comparison period control section comprises:
a counting part configured to count an output signal of the data comparison section by a limit setting value; and
a control signal generation part configured to generate the period control signal which is activated in response to the test operation mode and an output signal of the counting part.

8. A method for testing a semiconductor memory device, comprising:
primarily detecting a first defective address in response to first selected ones of addresses corresponding to a plurality of memory cells in a test operation mode;
outputting the detected address; and
secondarily detecting a second defective address in response to second selected ones of the addresses, wherein the second selected addresses are different from the first selected addresses.

9. The method of claim 8, further comprising:
storing test data in the plurality of memory cells in the test operation mode.

10. The method of claim 8, wherein the primarily detecting of the first defective address and the secondarily detecting of the first defective address comprise:
storing test data in the plurality of memory cells;
comparing the test data with data stored in the plurality of memory cells; and
storing an address of a corresponding memory cell in response to a comparison result.

11. The method of claim 8, wherein the primarily detecting of the first defective address and the secondarily detecting of the second defective address are repeated by a number of times initially set.

12. The method of claim 8, wherein each of the first and second selected addresses is set by using a first address of the selected addresses and a last address of the selected addresses.

13. A method for testing a semiconductor memory device, comprising:
performing a first test operation in response to first selected ones of addresses corresponding to a plurality of memory cells;
outputting a test result of the first test operation; and
performing a second test operation in response to second selected ones of the addresses, wherein the second selected addresses are different from the first selected addresses.

14. The method of claim 13, wherein the first and second test operations include the same test mode.

15. The method of claim 13, wherein the first and second test operations include test modes different from each other.

16. The method of claim 13, wherein the first and second test operations are repeated by a number of times initially set.

17. The method of claim 13, wherein each of the first and second selected addresses is set by using a first address of the selected addresses and a last address of the selected addresses.

18. The method of claim 13, further comprising:
storing the test result of the first test operation in storage units;
setting the first and second selected addresses based on a number of the storage units.

19. The method of claim 18, further comprising:
storing a test result of the second test operation in the storage units, after the outputting of the test result of the first test operation.
